(19) United States
(12) Patent Application Publication
(10) Pub. No.: US 2025/0176131 A1
(43) Pub. Date: May 29, 2025

(54) TWO-STAGE COOLING OF HEAT GENERATING COMPONENTS

(71) Applicant: ICEOTOPE GROUP LIMITED, South Yorkshire (GB)

(72) Inventors: Oliver HEYES, Sheffield (GB); Nathan LONGHURST, South Yorkshire (GB)

(21) Appl. No.: 18/842,585

(22) PCT Filed: Mar. 3, 2023
(86) PCT No.: PCT/GB2023/050498

§ 371 Date: Aug. 29, 2024

(30) Foreign Application Priority Data
Mar. 3, 2022 (GB) 2202965.6

(51) Int. Cl. H05K 7/20

(52) U.S. Cl. CPC H05K 7/20254; H05K 7/20263; H05K 7/20272; H05K 7/20772

(57) ABSTRACT

A module, used in cooling one or more heat generating components, comprises: a heat exchanger, having a plurality of ports for flow of a primary coolant carrying heat from the one or more heat generating components and for flow of a secondary coolant, the heat exchanger being configured to transfer heat from the primary coolant to the secondary coolant; and a volume compensator, fluidly coupled to the heat exchanger via one of the plurality of ports. The volume compensator has an internal volume configured to increase or decrease in size depending on pressure. A cooled electronics system comprising one more such modules is also provided.

### TECHNICAL FIELD OF THE DISCLOSURE

The disclosure concerns a module for use in cooling heat generating components.

### BACKGROUND TO THE DISCLOSURE

Computers, servers, disc drives and other devices used for data processing (referred to as Information Technology or IT) are usually housed within a case, enclosure or housing. In a server for instance, this enclosure is sometimes referred to as the server chassis, although the term “chassis” is used herein to relate to any type of overall housing used for electronic components. A server chassis typically adheres to a number of industry standards that specify the height of each chassis, referred to as 1 RU (one rack unit) or 1 OU (one open unit), these are also abbreviated to 1 U or 1 OU. The smaller of the two main standards is the 1 RU/1 U, which is 44.45 mm or 1.75 inches in height. Such units are sometimes referred to as a “blade” server in the sense of shape and style, although it may not be necessary for such a server chassis to slot or plug into a backplane, for example.

Different server products can utilise more than one RU/OU at a time for the chassis, for example a 2 U chassis uses two rack units. The size of each server chassis is usually kept to a minimum to maximise the amount of computing power per server rack (a server rack is the main housing to which server chassis are added).

Liquid cooling is increasingly used for removing heat from IT components. In one type of system, the electrical components are immersed in a coolant liquid, so as to provide a large surface area for heat exchange between the heat generating electrical components and the coolant. Such systems may use a single phase coolant, in which case the coolant remains in liquid phase or a phase-change coolant, where the liquid coolant evaporates and must be condensed for continuous, effective cooling.

Additionally or alternatively, cold plates are used, in which the liquid coolant flows through a cold plate that is typically in direct thermal contact with one or more IT components. For example, a closed loop cold plate may receive coolant, transfer heat from the one or more IT components to the coolant and direct the coolant to a heat exchanger, without the coolant directly contacting the one or more IT components. In some implementations, heat is transferred from the liquid coolant that flows through a cold plate to a secondary liquid coolant.

International Patent publication WO-2018/096362 (commonly assigned with the present disclosure) describes a cooling system in which a primary dielectric coolant liquid is provided within a chassis and used to cool electronic components housed within. The primary dielectric coolant liquid is pumped to a heat exchanger, where heat is transferred to a secondary liquid coolant. The heat exchanger is provided within the chassis and the secondary liquid coolant, which is typically water or water-based (advantageous as having a high specific heat capacity), is pumped to the chassis and the heat exchanger within, before then being pumped out of the chassis and may be shared between multiple chassis. Pipes that end with nozzles are provided for conveying the primary dielectric coolant from the heat exchanger to the electronic components being cooled.

International Patent publication WO-2019/048864 (also commonly assigned with the present disclosure) describes heat sinks and heat sink arrangements for an electronic device. Such a heat sink may allow a primary dielectric coolant to be accumulated adjacent a specific electronic component, thereby cooling the electronic component effectively. The coolant may flow out of the heat sink, by overflowing the heat sink and/or by one or more apertures in the heat sink, and join the remainder of the coolant in the chassis that cools other electronic components within. In this way, multiple levels of coolant may be provided and the total quantity of coolant required may be minimized. Pipes that end with nozzles are provided for conveying the primary dielectric coolant from a heat exchanger to each heat sink.

International Patent publication WO-2020/178579 (also commonly assigned with the present disclosure) relates to adaptations to a chassis of a module housing liquid-cooled IT and to a rack in which multiple such modules may be mounted.

International Patent publication WO-2020/234600 (also commonly assigned with the present disclosure) considers the possibility of using immersion cooling in a chassis (of the type described above, having a primary dielectric coolant) together with one or more closed loop cold plates in the same chassis. The coolant used for the closed loop cold plate, which is received from outside the chassis, may also act as a secondary coolant for receiving heat from the primary dielectric coolant. This takes place at a heat exchanger that is typically also within the chassis. Such an approach can provide high cooling performance and high efficiency.

The heat exchanger between the primary and secondary coolants is thus a key part in all of these systems. Constraints may be imposed on the heat exchanger implementation. For example the heat exchanger may be desirably small, especially if it is provided in the chassis. A plate heat exchanger can be preferred for this reason. It is often also desirable to allow disconnection between the heat exchanger and secondary coolant circuit without difficulty. For example (and again, especially if the heat exchanger is provided in the chassis), quick disconnect couplings to the heat exchanger may be provided for the secondary coolant. These allow the chassis to be removed from its mounting (for example, within a rack) straightforwardly.

In configurations of this type, the flow of secondary coolant within the heat exchanger may be disrupted during operation. It is desirable to mitigate problems that may arise in such implementations.

### SUMMARY OF THE DISCLOSURE

Against this background, there is provided a module for use in cooling one or more heat generating components as defined by claim 1. A cooled electronics system is also provided in accordance with claim 18. Other claims define advantageous and/or more detailed features.

A volume compensator is connected to one port of a heat exchanger that is used for transferring heat from a primary coolant to a secondary coolant. The volume compensator has an internal volume that increases or decreases in size depending on pressure. For example, forms of pressure regulator including a hydropneumatic device such as a water hammer arrestor, may be used for this purpose. Other options may include a resiliently biased mechanism (for instance, a spring-based device) or a volume with a diaphragm (made from a flexible material, for instance rubber or similar). Both the primary and secondary coolants are typically liquids and beneficially the coolants and/or module are designed for single-phase use.

It has been appreciated that an accidental closed loop may form in the module, particularly when the secondary coolant inlet and outlet of the module are disconnected (from a supply and drain or a loop). In that case, the secondary coolant may continue to heat, although no secondary coolant may flow. As a result, pressure may build up in the accidental closed loop, which can cause significant problems in the module or to external devices when the module is connected (or reconnected) to them. Such problems may include connector failure, leaks and other damage. The provision of a volume compensator may mitigate such problems.

The volume compensator is generally connected to a port of the heat exchanger configured for flow of the secondary coolant, but it may be connected to a port of the heat exchanger configured for flow of the primary coolant. Advantageously, the volume compensator is connected to a port configured for flow of coolant out of the heat exchanger. Quick disconnect couplings (a coupling with a non-return valve) are typically connected to at least some ports of the heat exchanger, generally ports for flow of the secondary coolant. The accidental closed loop may especially form when quick disconnect couplings are employed.

The volume compensator and heat exchanger may define the module, but more typically, the module may be defined by additional components. As such, the module may be a single unit for holding the heat generating components and primary coolant. A server blade or other IT unit (whether rack-mounted or otherwise) are examples of such modules. For instance, the heat exchanger is preferably within and/or attached to a housing (chassis) of the module, in which the heat generating components and primary coolant are contained. Typically then, the primary coolant arrives at the heat exchanger from within the housing (for example, a dielectric coolant, which may remain within the chassis), whereas at least some of the secondary coolant arrives from outside the housing and/or is directed from the heat exchanger to outside the housing (for instance, a facility coolant, which may be water or water-based).

The volume compensator may be connected to the heat exchanger via a T-connector, which may be space-efficient in certain designs. The T-connector may have three ports: a first port connected to the heat exchanger; a second port connected to the volume compensator; and a third port for flow of coolant to and/or from the heat exchanger. The three ports are thus typically arranged in a T-shape.

In one implementation, the volume compensator is located outside the chassis and/or to a quick disconnect coupling that is coupled to the heat exchanger. Additionally or alternatively, the heat exchanger has only two ports for flow of the secondary coolant and the volume compensator is connected to one of these ports (via a quick disconnect coupling, for instance).

In another implementation, the heat exchanger has two ports for flow of the primary coolant and four ports for flow of the secondary coolant. In other words, the heat exchanger has six ports in total. The primary coolant and secondary coolant are nonetheless advantageously kept isolated in the heat exchanger. For example, two of the four ports for flow of the secondary coolant may be located on the same side of the heat exchanger as the two ports for flow of the primary coolant and the other two of the four ports for flow of the secondary coolant may be located on the opposite side. The volume compensator may be connected to a first of the four ports for flow of the secondary coolant (typically the port configured for flow out of the heat exchanger). A second of the four ports for flow of the secondary coolant may be plugged. These first and second ports may be associated with each and/or on the same side of the heat exchanger. A third of the four ports (typically on the opposite side of the heat exchanger) is for receiving secondary coolant into the heat exchanger (from external the chassis) and a fourth of the four ports is for flow of the secondary coolant out of the heat exchanger (to external the chassis).

Optionally, more than one volume compensator may be provided, each connected to a different port of the heat exchanger. For example, a first volume compensator may be connected to a port for flow of a coolant out of the heat exchanger and a second volume compensator may be connected to a port for flow of a coolant into the heat exchanger. Such arrangements may be used to provide additional volume compensation as desired.

A coolant flow arrangement may also be provided in the module, for directing the primary coolant to the heat exchanger and/or from the heat exchanger to the one or more heat generating components. The coolant flow arrangement generally comprises one or more pumps located within the housing and may further include a piping arrangement (for directing coolant from the pump or pumps to the heat exchanger and/or from the heat exchanger towards the heat generating components). The coolant flow arrangement may also comprise a manifold, for splitting the primary coolant from the heat exchanger into multiple coolant flows for different heat generating components.

One or more heat sink arrangements may also be provided in the module. Each heat sink arrangement has an internal volume in which a coolant is received from the heat exchanger and accumulated. Heat is then transferred to the accumulated coolant one from a heat generating component, which may be mounted within the internal volume or on which the heat sink arrangement is mounted. The heat sink arrangements can take various forms. In one form, a heat sink arrangement may be a closed-loop cold plate, for example configured to receive secondary coolant from the heat exchanger. An alternative form for a heat sink arrangement accumulates primary coolant in the internal volume and allows the accumulated coolant to flows out of (for instance by overflowing) the internal volume. The effluent coolant is then used to cool other heat generating components (for example, providing multiple coolant at multiple levels within the module).

A cooled electronics system may comprise one or more modules (which may be mounted in a rack, for example) with a secondary heat exchanger for transferring heat from the secondary coolant to a heat sink (thereby providing a secondary coolant loop, where the cooled secondary coolant is returned to the module or modules). The secondary heat exchanger may be provided in a rack or external. One example of a secondary heat exchanger is a heat rejection unit. The secondary coolant from and/or to each module may be combined in series or parallel, through a secondary coolant piping arrangement.

### BRIEF DESCRIPTION OF THE DRAWINGS

The disclosure may be put into practice in a number of ways and preferred embodiments will now be described by way of example only and with reference to the accompanying drawings, in which:

FIG. 1 depicts a plan view of a liquid cooling module comprising an external volume compensator according to a first embodiment;

FIG. 2A shows a rear isometric view of the embodiment of FIG. 1;

FIG. 2B shows a front isometric view of the embodiment of FIG. 1;

FIG. 3A illustrates a rear isometric view of a heat exchanger with volume compensator for use in the embodiment of FIG. 1;

FIG. 3B shows a front isometric view of the heat exchanger with volume compensator illustrated in FIG. 3A;

FIG. 4 depicts a plan view of a liquid cooling module comprising an internal volume compensator according to a second embodiment;

FIG. 5A shows a rear isometric view of the embodiment of FIG. 4;

FIG. 5B shows a front isometric view of the embodiment of FIG. 4;

FIG. 6A shows a rear isometric view of a heat exchanger with volume compensator for use in the embodiment of FIG. 4;

FIG. 6B shows a front isometric view of the heat exchanger with volume compensator illustrated in FIG. 6A;

Like features are denoted by the same reference numerals throughout. All drawings may be understood as schematic in nature.

### DETAILED DESCRIPTION OF PREFERRED EMBODIMENTS

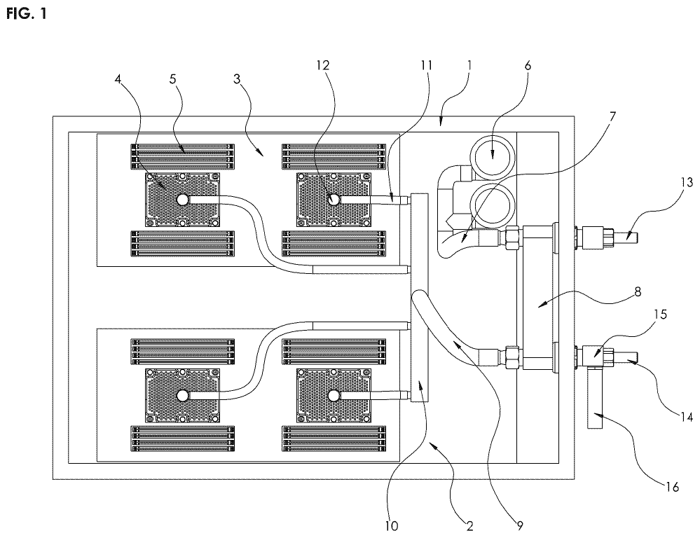

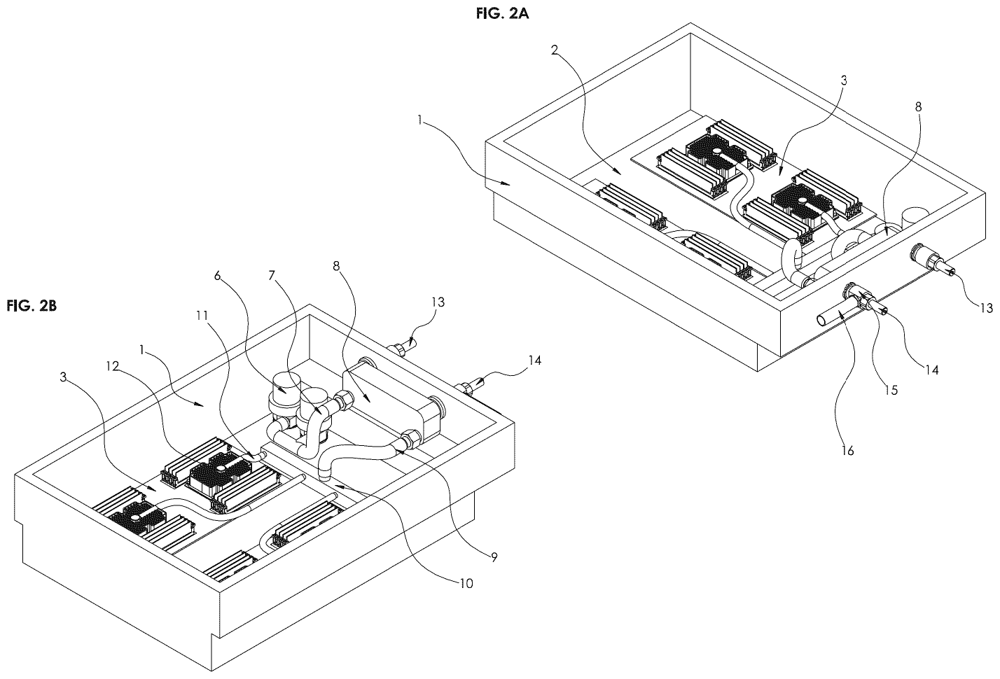

Referring first to FIG. 1, there is depicted a plan view of a liquid cooling module (for example, a blade server) comprising an external volume compensator. Reference is also made to FIG. 2A, in which there is shown a rear isometric view of the embodiment of FIG. 1 and to FIG. 2B, in which there is shown a front isometric view of the embodiment of FIG. 1.

In all of these drawings, the entire chassis of the module is shown, but without a lid (which would normally be provided in an assembled module). This comprises: a chassis 1, defining a volume 2 in which dielectric coolant can be located; motherboards 3; chips or integrated circuits (which may include any type of processor, CPU, GPU or otherwise) with heat sinks 4 mounted on the motherboards 3; DIMMs (or auxiliary electronic components) 5 also mounted on the motherboards 3; pumps 6; first connecting pipe 7; plate heat exchanger 8; second connecting pipe 9; primary coolant manifold 10; hose pipe connections 11; and nozzle 12. The plate heat exchanger 8 is within the chassis 1 and the module further includes quick disconnect couplings 13, 14 external the chassis 1 for receiving a secondary coolant (a facility coolant, which may be water or water-based) for provision into and out of the heat exchanger 8. The secondary coolant is received from and returned to a secondary coolant loop (not shown) outside the module chassis 1. The secondary coolant loop comprises a further heat exchanger (not shown) that cools the secondary coolant, transferring heat to a downstream heat sink (not shown). For example, a heat rejection unit may be suitable. All these features are known for providing a primary (dielectric) cooling circuit and second stage liquid cooling, as discussed in WO-2018/096362 and WO-2019/048864. In particular, the arrangement of processors with heat sinks 4, the first connecting pipe 7 (connecting the pump 6 to the plate heat exchanger 8) and the second connecting pipe 9 (connecting the plate heat exchanger 8 to the primary coolant manifold 10) are as described in WO-2019/048864. The flow rate of the primary coolant and/or secondary coolant may be set (or adjusted) to keep the primary and/or secondary coolants as liquids.

In addition, there is provided a “T” piece connector 15 and a volume compensator 16 that are mounted between the plate heat exchanger 8 and the quick disconnect coupling 14. The volume compensator 16 takes the form of a water hammer arrester in this example. When the module chassis 1 is disconnected form the secondary (facility) coolant loop via the quick disconnect couplings 13, 14, some of the facility coolant may be trapped in an accidental closed circuit, formed by the plate heat exchanger 8 and the quick disconnect couplings 13, 14. This accidental closed circuit may have a small volume of secondary (facility) coolant, for example around 70 cm³ to 1 litre (in some specific examples, volumes of approximately 30 cm³ to 100 cm³ on a relatively small module, 250 cm³ on a larger module and 1200 cm³ on a significantly larger module, for a 10 Kw system for instance, were measured).

This secondary coolant is typically already pressurised, because normal facility coolant circuits are operated at a pressure of 1.5 to 4 bar (1.5×10⁵ to 4×10⁵ Pa). This pressure is manageable, because the weakest part of the closed circuit is often the quick disconnect couplings 13, 14, which depending on the devices used can operate at up to anywhere between 4 bar (4×10⁵ Pa) and 20 bar (2×10⁶ Pa), for example approximately 7 or 8 bar (7 or 8×10⁵ Pa) or 16 bar (1.6×10⁶ Pa). Nevertheless, there are two issues that can cause the pressure to raise significantly and therefore cause problems.

First, in some cases, the quick disconnect couplings 13, 14 can be disconnected from the secondary coolant loop, but the chassis 1 may still be electrically powered. For example, a power cable may be used in a harness chain that provides electrical power to the chassis 1, when the module is pulled out of a rack. Indeed, this continuing power may be deliberate, so that the electronics in the module continues to operate during servicing of the chassis 1. When the couplings 13, 14 are disconnected, the electronic components on the motherboard 3 continue to generate heat and the pumps 6 continue to circulate the dielectric coolant. This heats the dielectric coolant in the plate heat exchanger 8 that in turn heats the remaining secondary (facility) coolant in the plate heat exchanger 8. In one example, this could raise the secondary coolant in the accidental closed circuit from 20 C to 60 C, a temperature increase of 40 C (typically, the ambient temperature may be 10 C to 20 C and the temperature could rise to as high as 80 C, so the temperature increase could be as high as 60 C or 70 C). This causes the secondary coolant to expand in the accidental closed circuit. The accidental closed circuit has a relatively small volume (compared with the secondary coolant loop) and no air. As a result, the pressure can increase significantly, with modelling suggesting that the pressure could be as high as 30 to 40 bar (3×10⁶ to 4×10⁶ Pa) or even 300 bar (3×10⁷ Pa) in larger modules. Such a pressure is significantly higher than the rated limit on the quick disconnect couplings 13, 14 and would likely cause their failure.

Second, even if the pressure increase in the accidental closed loop is manageable, a problem may still arise when the quick disconnect couplings 13, 14 are being reconnected to the secondary coolant loop. Then, a valve in the quick disconnect couplings 13, 14 may move backwards slightly, reducing the volume inside the accidental closed circuit. Even a small reduction in volume can cause a significant increase in pressure. In systems where the coupling to the quick disconnect couplings 13, 14 is manual, this pressure increase may simply make the couplings difficult to reattach. Moreover, because one coupling is attached at a time, the reduction in volume is only on a per coupling basis. In contrast, the chassis 1 may be provided on slide rails with blind mate couplings, in which case, the volume reduction and resultant pressure increase are much more significant. The chassis 1 and components mounted within is typically heavy (up to 150 kg in known designs), such that when the chassis 1 is pushed back into rack, the engagement force and speed on the couplings can be high. Moreover, both couplings engage at the same time reducing the volume significantly. The quick disconnect couplings 13, 14 and associated couplings on the secondary coolant loop may thus be damaged and other failures may follow.

Both of these issues can cause significant damage to the quick disconnect couplings 13, 14 on the chassis 1 and the counterpart couplings on the facility cooling side. Even if quick disconnect couplings are not used, couplings on the facility cooling side may fail in certain configurations. If the couplings on the facility side fail, there can be significant coolant leaks.

The volume compensator 16 allows the volume inside the accidental closed loop to increase, reducing the pressure in this accidental closed loop. Only a small additional volume may eliminate the pressure issue. In an example, a water hammer arrester marketed under the product identification 660-SERIES by the Sioux Chief Manufacturing

Company may be used. These components are specifically designed to work with water hammer and operate by moving a piston to provide additional volume. A pressurized chamber behind the piston provides compression resistance. For example, such water hammer arresters may actuate at a pressure of approximately 3 bar (3×10⁵ Pa), which is less than the approximate 7 bar (7×10⁵ Pa) working limit of the quick disconnect couplings 13, 14 typically employed.

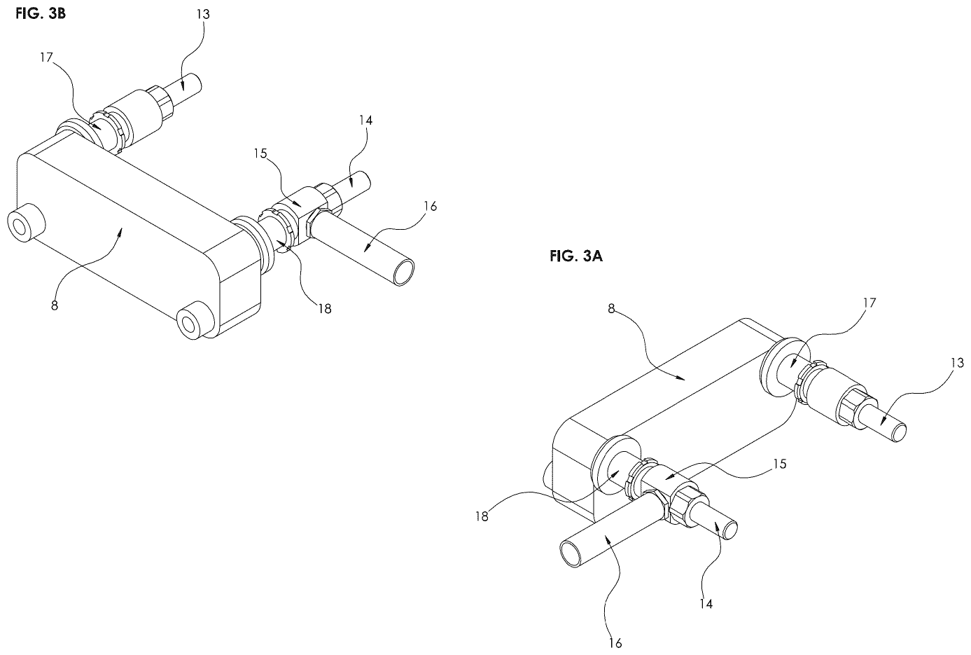

Referring next to FIG. 3A, there is illustrated a rear isometric view of a heat exchanger with volume compensator for use in the embodiment of FIG. 1. Reference is also made to FIG. 3B, in which there is shown a front isometric view of the heat exchanger with volume compensator illustrated in FIG. 3A. These drawings show the circuit for the closed plate heat exchanger 8 without the chassis and primary coolant circuit. This is the circuit that can reach a high pressure. An inlet port 17 and an outlet port 18 of the plate heat exchanger 8 are also shown, with the “T” piece connector 15 and volume compensator 16 connected to the outlet port 18. It is noted that these components could alternatively be connected to the inlet port 17. The “T” piece connector 15 can rotate so that the volume compensator 16 can be mounted in different positions depending on the configuration. Optionally, a second additional volume compensator (not shown) could be added to the inlet port 17 of the plate heat exchanger port 8, if more volume compensation were desired.

According to a general sense, there may thus be considered a module for use in cooling one or more heat generating components. In its most basic form, such a module may comprise: a heat exchanger (for example, a plate heat exchanger), having a plurality of ports for flow of a primary coolant carrying heat from the one or more heat generating components and for flow of a secondary coolant, the heat exchanger being configured to transfer heat from the primary coolant to the secondary coolant; and a volume compensator, connected to (or fluidly coupled to the heat exchanger via) one port of the plurality of ports. Advantageously, an internal volume of the volume compensator (which may be fluidly coupled to the heat exchanger via the one port) is configured to increase or decrease in size depending on pressure (in the internal volume). The heat exchanger (and preferably the whole module) is beneficially configured to keep the secondary coolant and the primary coolant isolated from each other, for example by the use of isolated chambers for the two coolants.

In typical embodiments, a quick disconnect coupling (or a coupling with a non-return valve) is connected to each of at least one (or more generally two, for example, an inlet and an outlet) of the ports, typically for flow of the secondary coolant.

More typically, the module further comprises a housing, for containing the heat generating components and the primary coolant. Then, the heat exchanger is generally within and/or attached to the housing. Although an external heat exchanger is possible, it should be at least fixed to the chassis. In any case, the primary coolant may thus be received at the heat exchanger from within the housing (as the primary coolant is normally constrained to within the housing and does not leave the housing). At least some of the secondary coolant is then received at the heat exchanger from outside the housing and/or is directed from the heat exchanger to outside the housing.

The volume compensator may comprise (or be) a hydropneumatic device, for instance, a water hammer arrestor. Advantageously, the port to which the volume compensator is connected is configured for flow of the secondary coolant. Additionally or alternatively, the port to which the volume compensator is connected is configured for flow of coolant out of the heat exchanger (that is, an outlet). In some implementations, the volume compensator is connected to the port of the heat exchanger via a T-connector. This may allow coolant to flow out of (or into) the heat exchanger through the same port to which the volume compensator is connected.

In an embodiment, the volume compensator is located outside the chassis. Additionally or alternatively, the volume compensator is connected to a quick disconnect coupling that is connected to the port of the heat exchanger (typically, also via the T-connector).

Optionally, the volume compensator is a first volume compensator connected to a first port of the plurality of ports. Then, the module may further comprise a second volume compensator, connected to a second port of the plurality of ports. For example, the first port may be configured for flow of a coolant (for instance, the secondary coolant) out of the heat exchanger. Then, the second port may be configured for flow of the coolant into the heat exchanger. Each of the first and second volume compensators may be connected to the respective ports of the heat exchanger via a respective, different T-connector.

A coolant flow arrangement may also be provided in the module, configured to direct the primary coolant to the heat exchanger and/or from the heat exchanger to the one or more heat generating components. For instance, the coolant flow arrangement may comprise at least one pump (and in some implementations, more than one pump) located within the housing. The coolant flow arrangement may further comprise a piping arrangement. The piping arrangement may be configured to transfer primary coolant from the pumps to the heat exchanger and/or from the heat exchanger to the one or more heat generating components. Optionally, the coolant flow arrangement comprises a manifold, arranged to receive some of the primary coolant from the heat exchanger and provide multiple coolant flows, each coolant flow for a respective heat generating component. In this case, the piping arrangement may be configured to transfer primary coolant from each of the multiple coolant flows provided by the manifold to a respective one of the multiple heat generating components.

In an implementation, a heat sink arrangement may be configured to receive some of the primary coolant from the heat exchanger and to accumulate received coolant in an internal volume of the heat sink arrangement. This may be achieved such that heat is transferred to the accumulated received coolant from one of the heat generating components thermally (conductively) coupled to the heat sink arrangement. For example, the one of the heat generating components may be located inside the internal volume of the heat sink arrangement or the heat sink arrangement may be mounted on the one of the heat generating components, such that heat transfers from the heat generating components to the internal volume of the heat sink arrangement. Advantageously, the heat sink arrangement is configured such that coolant accumulated in the internal volume of the heat sink arrangement flows out of (through an aperture and/or by overflowing) the internal volume of the heat sink arrangement and is used to cool at least one other of the heat generating components (that are not thermally and/or conductively coupled to the heat sink arrangement). Multiple heat sink arrangements may be used within a housing, each heat sink arrangement for cooling a respective one or more of the heat generating components. More details of such heat sink arrangements may be found in WO-2019/048864.

In another aspect, a cooled electronics system may be considered, comprising: one or more modules, each as described herein (which may be mountable or mounted in a rack, for instance); and a secondary heat exchanger, configured to receive the secondary coolant from the one or more modules, to cool the received secondary coolant by transferring heat from the received secondary coolant to a heat sink (for example, air or another liquid or gaseous coolant) and to return the cooled secondary coolant to the one or more modules. Thus, a secondary coolant loop may be provided.

The cooled electronics system may further comprise a secondary coolant piping arrangement, arranged to transfer the secondary coolant between the one or more modules and the secondary heat exchanger, such that the secondary coolant from each of the one or more modules is combined. The secondary coolant may be combined in series (that is, secondary coolant flows from one module to the next, before flowing the heat exchanger) and/or in parallel (that is, flow of secondary coolant is split between more than one module, before recombining upstream the heat exchanger).

Advantageously, the heat exchanger and/or module and/or system may be configured to maintain the primary and/or secondary coolants in liquid form (that is, single phase coolants).

Reference to further specific implementations will now be made. However, further discussion according to these general senses of the disclosure will be provided subsequently.

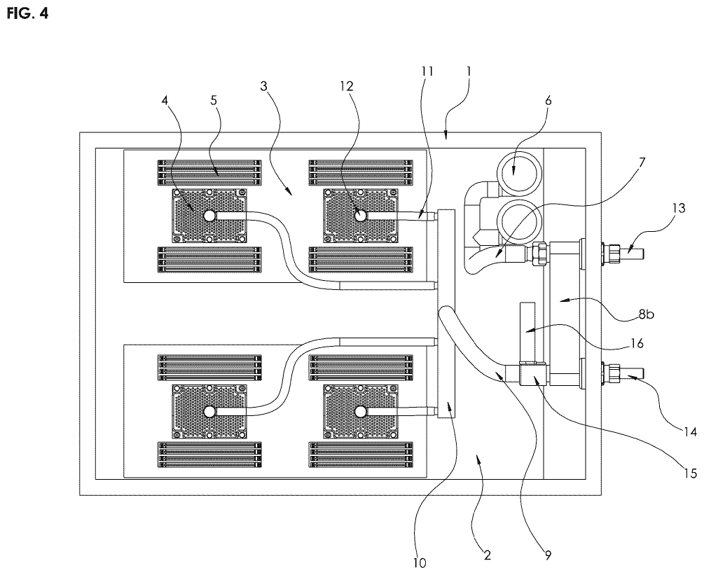

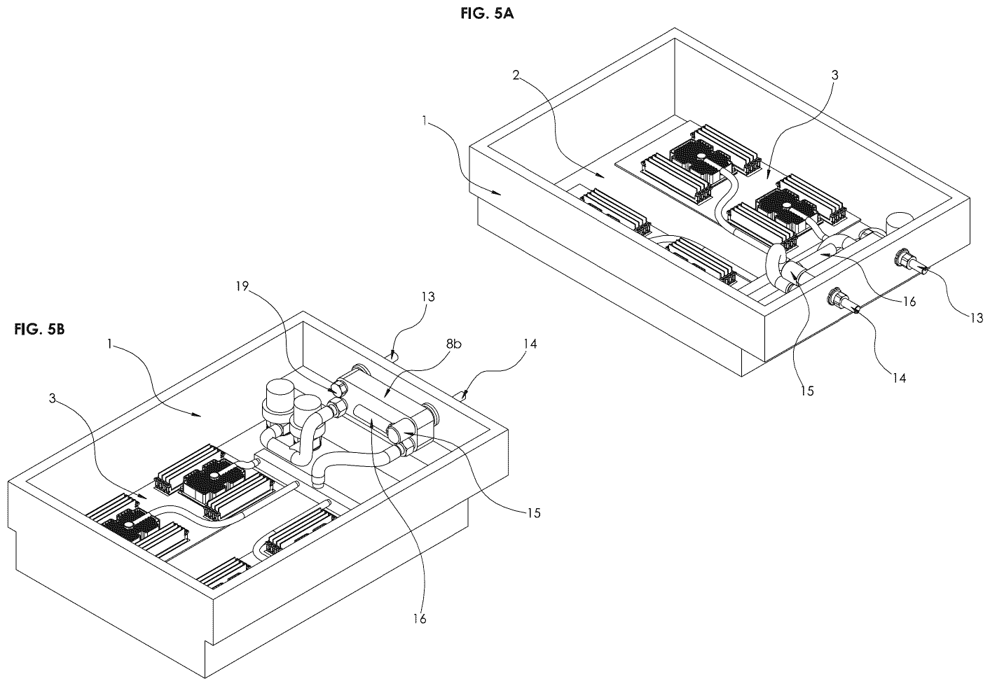

Referring next to FIG. 4, there is depicted a plan view of a liquid cooling module comprising an internal volume compensator according to a second embodiment. Reference is also made to FIG. 5A, showing a rear isometric view of the embodiment of

FIG. 4, and FIG. 5B, showing a front isometric view of the embodiment of FIG. 4. In all of these drawings, the entire chassis is illustrated, but without a lid (which would normally be additionally be provided). As noted above, where the same components are shown as illustrated in another drawing, identical reference numerals are used.

In this alternative configuration, the “T” piece connector 15 and the volume compensator 16 are on the inside of the chassis 1. This is advantageously possible by use of a six-port plate heat exchanger 8b. Such a heat exchanger is described in co-pending International patent application PCT/EP2021/082224 (co-assigned with the present disclosure), but a brief explanation of this device will be provided for completeness.

This heat exchanger has two isolated chambers: a first for primary coolant; and a second for secondary coolant. A thermally conductive interface (for example, a wall made from a thermally conductive material) separates the two chambers, allowing transfer of heat without any exchange of coolant. The second chamber has two inlets (inlet ports) and two outputs (outlet ports) as well as at least two pathways therethrough (that is, each pathway provides a path from an inlet to an outlet). Each pathway provides a route for the liquid coolant between different combinations of the inlet and outlet ports, and at least one of the pathways does not pass by or make contact with the thermally conductive interface through which heat can pass to the other chamber of the heat exchanger. All the pathways are fluidly connected and reside within the same chamber of the heat exchanger being fluidly separate to any other chamber of the heat exchanger.

Thus, one inlet and one outlet for the secondary coolant, referred to below as the main secondary coolant inlet and main secondary coolant outlet respectively, are provided on one side of the heat exchanger 8b (the same side as the quick disconnect couplings 13, 14). One inlet and one outlet for the secondary coolant are provided on the opposite side of the heat exchanger 8b (together with the inlet and outlet for the primary coolant), referred to below as the auxiliary secondary coolant inlet and auxiliary secondary coolant outlet respectively. This configuration allows secondary coolant to pass through from the outside of the chassis to inside the chassis, where it may be used in one or more cold plates, for example. In addition, the secondary coolant may receive heat from the primary coolant within the heat exchanger 8b. The “T” piece connector 15 and the volume compensator 16 are connected to the auxiliary secondary coolant outlet. A plug 19 is provided in the auxiliary secondary coolant inlet. A benefit of this configuration is that it makes better use of space. The front to back length of the module including the volume compensator 16 is reduced.

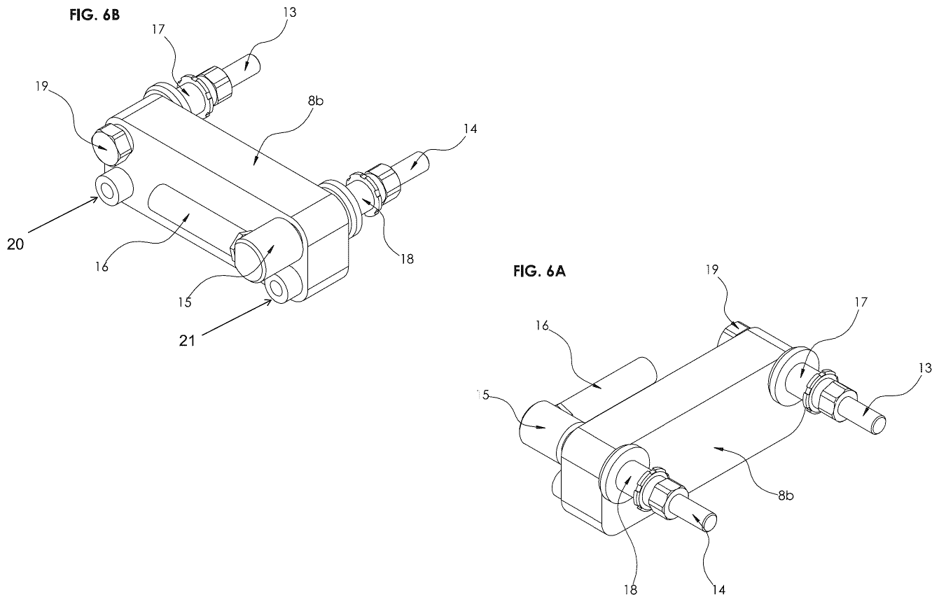

Reference is also made to FIG. 6A, in which there is shown a rear isometric view of a heat exchanger 8b with volume compensator 16 for use in the embodiment of FIG. 4, and FIG. 6B, in which a front isometric view of the heat exchanger with volume compensator illustrated in FIG. 6A is shown. The quick disconnect couplings 13, 14 are connected directly to the respective main secondary coolant inlet port 17 and main secondary coolant outlet port 18 of the plate heat exchanger 8b. The primary coolant inlet 20 and the primary coolant outlet 21 are also visible.

In an alternative version of this configuration, the “T” piece connector 15 could be removed and the volume compensator could be threaded directly into the plate heat exchanger 8b. This could be a better use of space in some configurations.

As with the external volume compensator described earlier, the plug 19 could be removed and an additional volume compensator (not shown) could be added to this port if more volume compensation were required. In fact, four volume compensators could be implemented if required, each connected to a respective one of the ports for flow of the secondary coolant. T-connectors would then be required for at least some of the ports, to allow the flow of secondary coolant into and out of the heat exchanger. A double T-joint may be used to mount two volume compensators on one port, for instance.

In a further alternative, the auxiliary secondary coolant inlet and the auxiliary secondary coolant outlet could be used for transferring secondary coolant to one or more cold plates provided inside the chassis. Each cold plate may be attached to a respective heat generating component (or multiple components) for transferring heat from the respective heat generating component or components to the secondary coolant flowing through the cold plate. The secondary coolant would then flow back through the heat exchanger and return to the secondary coolant loop via the main secondary coolant outlet. This describes a closed-loop cold plate implementation.

Returning to the general sense of the disclosure discussed above, further optional features may be considered. For example, in an implementation, the heat exchanger may have two ports for flow of the primary coolant (one inlet and one outlet, for instance) and four ports for flow of the secondary coolant (two inlets and two outlets, for instance). For example, two of the four ports for flow of the secondary coolant may be provided on one side of the heat exchanger. Then, the two ports for flow of the primary coolant and the other two of the four ports for flow of the secondary coolant may be provided on an opposite side of the heat exchanger.

In this case, the volume compensator is advantageously connected to a first of the four ports for flow of the secondary coolant. Typically, this is one of the two of the four ports for flow of the secondary coolant (for example, an outlet) provided on the opposite side of the heat exchanger. Optionally, a second port of the four ports for flow of the secondary coolant is plugged. The second port may also be one of the two of the four ports for flow of the secondary coolant (for example, an inlet) provided on the opposite side of the heat exchanger. More generally, the first port may be associated with and/or on the same side of the heat exchanger as the second port. A third port of the four ports for flow of the secondary coolant may be configured for flow of the secondary coolant into the heat exchanger (from external the chassis) and a fourth port of the four ports for flow of the primary coolant may be configured for flow of the secondary coolant out of the heat exchanger (from external the chassis). The third and fourth ports are typically located on the same side of the heat exchanger, which is the opposite side of the heat exchanger from the first and second ports.

In an implementation, a heat sink arrangement may be configured to receive some of the secondary coolant from the heat exchanger and to accumulate received coolant in an internal volume of the heat sink arrangement, such that heat is transferred to the accumulated received coolant from one of the heat generating components thermally (conductively) coupled to the heat sink arrangement. For example, the heat sink arrangement may comprise a closed-loop cold plate.

Although specific embodiments have now been described, the skilled person will appreciate that various modifications and alternations are possible. As discussed above, the arrangement of components, heat sinks, support structures and other configurations may be varied, combined or otherwise configured in a range of different ways, of which those disclosed herein are simply examples. The configuration of the electronic device cooled by the heat sink and/or other electronic devices may vary significantly. The exact shape and/or size of the heat sink device may also be modified. The structure of the heat sink device may also change, for example using other multi-part assemblies or as an integrally constructed device. The volume compensator could be connected to a port of the heat exchanger configured for flow of the primary coolant in some configurations.

Other options for a volume compensator may be considered. One example may use a resiliently biased mechanism (for instance with a spring), rather than a hydropneumatic approach. Such a device may be similar to a car radiator cap, for example. Another possibility may use a volume with a diaphragm. On one side of the diaphragm a reference pressure may be set. Thus, the volume on the other side of the diaphragm will change depending on the pressure difference across the diaphragm (which is typically made from a flexible material, for instance rubber or similar).

A further possible, alternative configuration may include the use of quick disconnect couplings in the primary coolant circuit. For example, these may be connected one or both of the ports of the heat exchanger used for the primary coolant. Such quick disconnect couplings could, for example, allow the rapid removal of heat generating components (for instance, electronics or a server board) from the chassis. As with the use of quick disconnect couplings in the secondary coolant circuit, the presence of non-return valves between the pumps and the heat exchanger could create an accidental closed loop. In this case, the use of a volume compensator connected to one of the heat exchanger ports for the flow of primary coolant could be beneficial. The likelihood of continued temperature rise in this case is less than for an accidental closed loop in the secondary coolant circuit. This is because the component that generates the heat (for instance, a server board) may have been removed from the chassis.

All of the features disclosed herein may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

1. A module for use in cooling one or more heat generating components, comprising:
a heat exchanger, having a plurality of ports for flow of a primary coolant carrying heat from the one or more heat generating components and for flow of a secondary coolant, the heat exchanger being configured to transfer heat from the primary coolant to the secondary coolant; and
a volume compensator, fluidly coupled to the heat exchanger via one of the plurality of ports, said volume compensator having an internal volume configured to increase or decrease in size depending on pressure.

2. The module for claim 1, further comprising:
a housing, for containing the heat generating components and the primary coolant; and
wherein the heat exchanger is within and/or attached to the housing, the primary coolant being received at the heat exchanger from within the housing and at least some of the secondary coolant being received at the heat exchanger from outside the housing and/or being directed from the heat exchanger to outside the housing.

3. The module of claim 1, wherein the volume compensator comprises one of: a hydropneumatic device; a resiliently biased mechanism; a volume with a diaphragm.

4. The module of claim 1, wherein one or more of:
a quick disconnect coupling is connected to each of at least one of the ports;
the one port is configured for flow of the secondary coolant; and
the one port is configured for flow of coolant out of the heat exchanger.

5. The module of claim 1, wherein the volume compensator is connected to the one port via a T-connector.

6. The module of claim 1, wherein one or both of:
the volume compensator is located outside the chassis; and
the volume compensator is connected to a quick disconnect coupling that is connected to the one port.

7. The module of claim 1, wherein the volume compensator is a first volume compensator connected to a first port of the plurality of ports, the module further comprising a second volume compensator, connected to a second port of the plurality of ports.)

8. The module of claim 7, wherein the first port is configured for flow of a coolant out of the heat exchanger and the second port is configured for flow of the coolant into the heat exchanger.

9. The module of claim 1, wherein the heat exchanger has two ports for flow of the primary coolant and four ports for flow of the secondary coolant.

10. The module of claim 9, wherein the one port is a first of the four ports for flow of the secondary coolant.

11. The module of claim 10, wherein a second port of the four ports for flow of the secondary coolant is plugged.

12. The module of claim 10, wherein a third port of the four ports for flow of the secondary coolant is configured for flow of the secondary coolant into the heat exchanger and a fourth port of the four ports for flow of the primary coolant is configured for flow of the secondary coolant out of the heat exchanger.

13. The module of claim 1, further comprising:
a coolant flow arrangement, configured to direct the primary coolant to the heat exchanger and/or from the heat exchanger to the one or more heat generating components.

14. The module of claim 13, wherein the coolant flow arrangement comprises at least one pump located within the housing.

15. The module of claim 13, wherein the coolant flow arrangement comprises a manifold, arranged to receive some of the primary coolant from the heat exchanger and provide multiple coolant flows, each coolant flow for a respective heat generating component.

16. The module of claim 1, further comprising:
a heat sink arrangement, configured to receive some of the primary coolant or the secondary coolant from the heat exchanger and to accumulate received coolant in an internal volume of the heat sink arrangement, such that heat is transferred to the accumulated received coolant from one of the heat generating components thermally coupled to the heat sink arrangement.

17. The module of claim 16, wherein the heat sink arrangement comprises a closed-loop cold plate or wherein the heat sink arrangement is configured such that coolant accumulated in the internal volume of the heat sink arrangement flows out of the internal volume of the heat sink arrangement and is used to cool at least one other of the heat generating components.

18. A cooled electronics system, comprising:
one or more modules, each module for use in cooling one or more heat generating components and comprising:
a heat exchanger, having a plurality of ports for flow of a primary coolant carrying heat from the one or more heat generating components and for flow of a secondary coolant, the heat exchanger being configured to transfer heat from the primary coolant to the secondary coolant; and
a volume compensator, fluidly coupled to the heat exchanger via one of the plurality of ports, said volume compensator having an internal volume configured to increase or decrease in size depending on pressure; and
a secondary heat exchanger, configured to receive the secondary coolant from the one or more modules, to cool the received secondary coolant by transferring heat from the received secondary coolant to a heat sink and to return the cooled secondary coolant to the one or more modules.

19. The cooled electronics system of claim 18, further comprising:
a secondary coolant piping arrangement, arranged to transfer the secondary coolant between the one or more modules and the secondary heat exchanger, such that the secondary coolant from each of the one or more modules is combined.
